(19) United States
(12) Patent Application Publication
(10) Pub. No.: US 2025/0311288 A1
(43) Pub. Date: Oct. 2, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Yuta Sato, Himeji Hyogo (JP); Takashi Ishikawa, Tatsuno Hyogo (JP); Koji Onishi, Ibo Hyogo (JP)

(21) Appl. No.: 18/828,546

(22) Filed: Sep. 9, 2024

(30) Foreign Application Priority Data
Apr. 2, 2024 (JP) 2024-059642

(51) Int. Cl. H01L 29/78; H01L 29/66

(52) U.S. Cl. CPC H10D 30/668; H10D 30/0297

(57) ABSTRACT

According to one embodiment, a semiconductor device includes first and second electrodes, first to fifth semiconductor regions, and first and second conductive portions. A first depth in a first direction from an upper surface of the fourth semiconductor region to a lower end of a first insulating layer is 1.05 μm or less. A distance in the first direction from the upper surface of the fourth semiconductor region to a boundary between the first semiconductor region and the second semiconductor region is 2.8 μm or more. A ratio of the distance to the first depth is between 2.15 to 3.05. A second depth in the first direction from the upper surface of the fourth semiconductor region to a lower end of a second insulating layer is 1.05 μm or more. A ratio of the distance to the second depth is between 2.15 to 3.05.

### CROSS-REFERENCE TO RELATED APPLICATIONS

This application is based upon and claims the benefit of priority from Japanese Patent Application No. 2024-059642, filed on Apr. 2, 2024; the entire contents of which are incorporated herein by reference.

### FIELD

Embodiments of the present invention generally relate to a semiconductor device.

### BACKGROUND

Semiconductor devices such as metal oxide semiconductor field effect transistors (MOSFETs) are used for power conversion or other applications. It is desirable for the breakdown capability of the semiconductor device to be high.

### BRIEF DESCRIPTION OF THE DRAWINGS

FIG. 1 is a plan view illustrating a semiconductor device according to an embodiment;

FIG. 2 is an enlarged perspective cross-sectional view of part II of FIG. 1;

FIG. 3 is a III-III cross-sectional view of FIG. 1;

FIGS. 4A and 4B are cross-sectional views illustrating a method for manufacturing the semiconductor device according to the embodiment;

FIGS. 5A and 5B are cross-sectional views illustrating the method for manufacturing the semiconductor device according to the embodiment;

FIG. 6 is a partially enlarged cross-sectional view of FIG. 3;

FIG. 7 is a graph illustrating a profile of the n-type impurity concentration in the semiconductor device according to the embodiment;

FIGS. 8A to 8C show simulation results showing characteristics of the semiconductor device according to the embodiment;

FIG. 9 shows other simulation results showing the characteristics of the semiconductor device according to the embodiment;

FIG. 10 shows other simulation results showing the characteristics of the semiconductor device according to the embodiment;

FIG. 11 shows other simulation results showing the characteristics of the semiconductor device according to the embodiment;

FIGS. 12A to 12F show other simulation results showing the characteristics of the semiconductor device according to the embodiment; and

FIG. 13 is a cross-sectional view illustrating a part of a semiconductor device according to a modification of the embodiment.

### DETAILED DESCRIPTION

According to one embodiment, a semiconductor device includes a first electrode, a first semiconductor region of a first conductivity type, a second semiconductor region of the first conductivity type, a third semiconductor region of a second conductivity type, a fourth semiconductor region of the first conductivity type, a first conductive portion, a fifth semiconductor region of the second conductivity type, a second conductive portion, and a second electrode. The first semiconductor region is provided on the first electrode. The second semiconductor region includes a first portion and a second portion located around the first portion along a first plane that is perpendicular to a first direction from the first electrode to the first semiconductor region. The second semiconductor region is provided on the first semiconductor region, an impurity concentration of the first conductivity type in the second semiconductor region being less than an impurity concentration of the first conductivity type in the first semiconductor region. The third semiconductor region is provided on the first portion. The fourth semiconductor region is provided on the third semiconductor region. The first conductive portion faces the third semiconductor region via a first insulating layer in a second direction that is perpendicular to the first direction from the first electrode to the first semiconductor region. A first depth in the first direction from an upper surface of the fourth semiconductor region to a lower end of the first insulating layer is not less than 1.05 μm. A distance in the first direction from the upper surface of the fourth semiconductor region to a boundary between the first semiconductor region and the second semiconductor region is not less than 2.8 μm. A ratio of the distance to the first depth is not less than 2.15 and not more than 3.05. The fifth semiconductor region is provided on the second portion. The second conductive portion faces the fifth semiconductor region via a second insulating layer in the second direction. A second depth in the first direction from the upper surface of the fourth semiconductor region to a lower end of the second insulating layer is not less than 1.05 μm. A ratio of the distance to the second depth is not less than 2.15 and not more than 3.05. The second electrode is provided on the third semiconductor region, the fourth semiconductor region, and the fifth semiconductor region.

Embodiments of the invention will now be described with reference to the drawings. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated. In the drawings and the specification of the application, components similar to those described thereinabove are marked with like reference numerals, and a detailed description is omitted as appropriate.

In the following descriptions and drawings, notations of n⁺, n, n and p, p-represent relative heights of impurity concentrations in conductivity types. That is, the notation with “+” shows a relatively higher impurity concentration than an impurity concentration for the notation without any of “+” and “−”. The notation with “−” shows a relatively lower impurity concentration than the impurity concentration for the notation without any of them. These notations represent relative height of a net impurity concentration after mutual compensation of these impurities when respective regions include both of a p-type impurity and an n-type impurity.

The embodiments described below may be implemented by reversing the p-type and the n-type of the semiconductor regions.

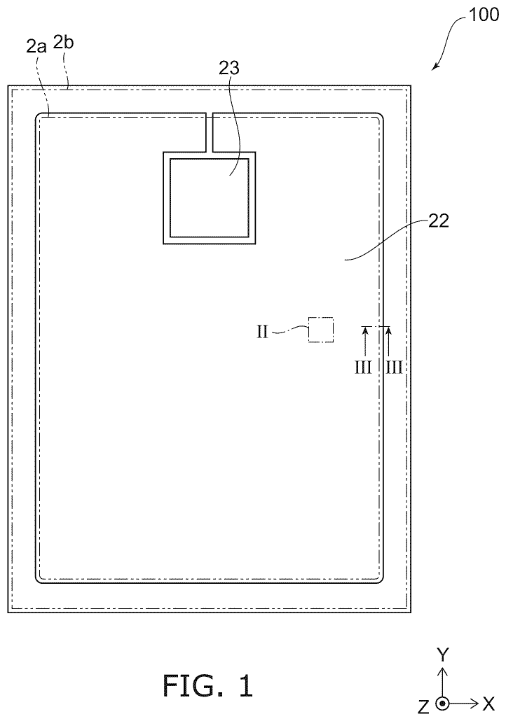

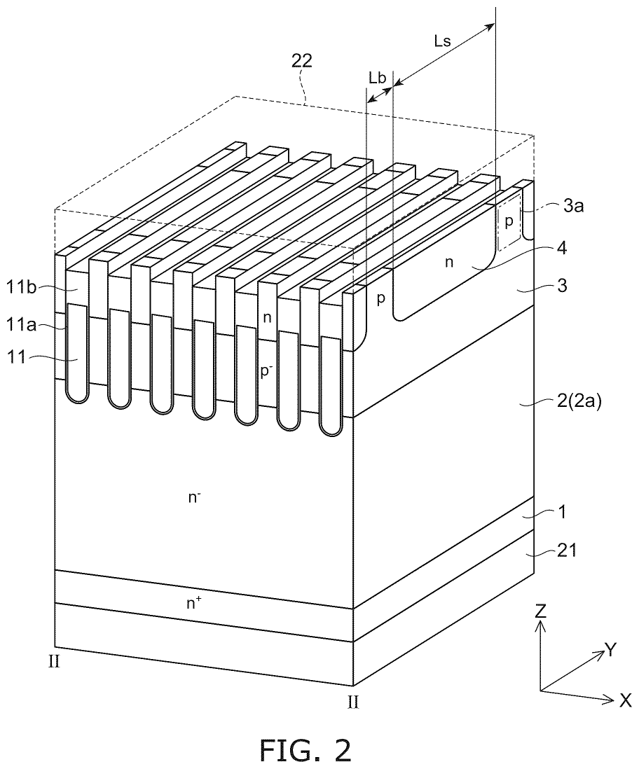

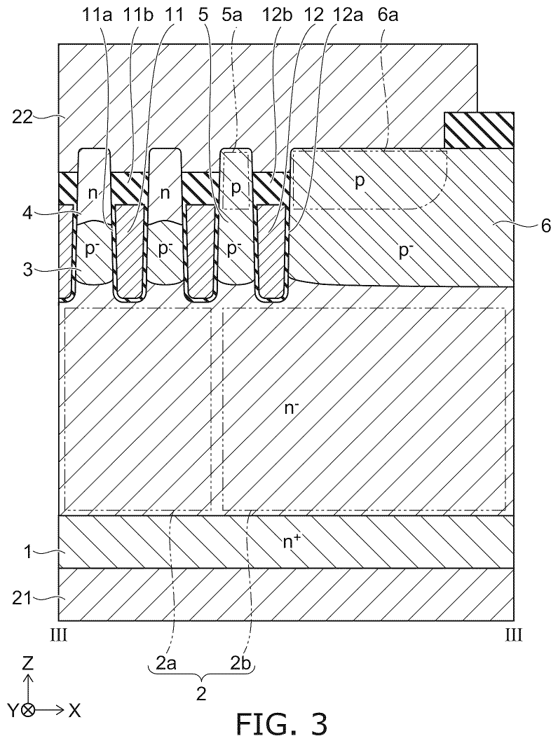

FIG. 1 is a plan view illustrating a semiconductor device according to an embodiment. FIG. 2 is an enlarged perspective cross-sectional view of part II of FIG. 1. FIG. 3 is a III-III cross-sectional view of FIG. 1.

The semiconductor device 100 according to the embodiment is a MOSFET. As shown in FIGS. 1 to 3, the semiconductor device 100 includes an n⁺-type (a first conductivity type) drain region 1 (a first semiconductor region), an n⁻-type drift region 2 (a second semiconductor region), a p⁻-type (a second conductivity type) base region 3 (a third semiconductor region), an n-type source region 4 (a fourth semiconductor region), and a p⁻-type semiconductor region 5 (a fifth semiconductor region), a p⁻-type semiconductor region 6, a first conductive portion 11, a first insulating layer 11a, a second conductive portion 12, a second insulating layer 12a, a drain electrode 21 (a first electrode), a source electrode 22 (a second electrode), and a gate pad 23. In FIG. 2, the source electrode 22 is shown with a dashed line.

An XYZ orthogonal coordinate system is used in the description of the embodiments. A direction from the drain electrode 21 toward the n⁺-type drain region 1 is taken as a Z-direction (a first direction); and two mutually-orthogonal directions perpendicular to the Z-direction are taken as an X-direction (a third direction) and a Y-direction (a second direction). In the description, the direction from the drain electrode 21 toward the n⁺-type drain region 1 is called “up”, and the opposite direction is called “down/lower than”. These directions are based on the relative positional relationship between the drain electrode 21 and the n⁺-type drain region 1, and are independent of the direction of gravity.

As shown in FIG. 1, the source electrode 22 and the gate pad 23 are provided on the upper surface of the semiconductor device 100. The source electrode 22 and the gate pad 23 are separated from each other and electrically isolated.

As shown in FIG. 2, the drain electrode 21 is provided on the lower surface of the semiconductor device 100. The n⁺-type drain region 1 is provided on the drain electrode 21 and is electrically connected to the drain electrode 21. The n⁻-type drift region 2 is provided on the n⁺-type drain region 1. The n⁻-type drift region 2 is electrically connected to the drain electrode 21 via the n⁺-type drain 10 region 1. The n-type impurity concentration in the n-type drift region 2 is less than the n-type impurity concentration in the n+-type drain region 1.

As shown in FIGS. 1 to 3, the n⁻-type drift region 2 includes a first portion 2a and a second portion 2b. The second portion 2b is located around the first portion 2a in the X-Y plane (a first plane). The first portion 2a is located in a cell region. The cell region is the region through which a current mainly flows during the operation of the semiconductor device 100. The second portion 2b is located in a termination region. The termination region is the region where the depletion layer spreads toward the outer periphery of the semiconductor device 100 when the semiconductor device 100 withstands a voltage.

As shown in FIGS. 2 and 3, the p⁻-type base region 3 is provided on the first portion 2a. The n-type source region 4 is provided on the p-type base region 3. The first conductive portion 11 is provided on the first portion 2a with the first insulating layer 11a interposed. The first conductive portion 11 faces the p⁻-type base region 3 in the X-direction via the first insulating layer 11a.

As shown in FIG. 3, the p-type semiconductor region 5 is provided on the second portion 2b. The second conductive portion 12 is provided on the second portion 2b with the second insulating layer 12a interposed. The second conductive portion 12 faces the p⁻-type semiconductor region 5 in the X-direction via the second insulating layer 12a. 35

An n-type semiconductor region such as the n-type source region 4 is not provided on the p⁻-type semiconductor region 5. For example, in the upper part of the p⁻-type semiconductor region 5, at a position aligned with the n-type source region 4 in the X-direction, there is no n-type semiconductor region, and a part of the p⁻-type semiconductor region 5 exists.

The p⁻-type semiconductor region 6 is provided on the second portion 2b as shown in FIG. 3. The p⁻-type semiconductor region 5 is positioned between the p⁻-type base region 3 and the p⁻-type semiconductor region 6 in the X-direction. The second conductive portion 12 is positioned between the p⁻-type semiconductor region 5 and the p⁻-type semiconductor region 6 in the X-direction. The length of the p⁻-type semiconductor region 6 in the X-direction is greater than the length in the X-direction of the p⁻-type semiconductor region 5.

The source electrode 22 is provided on the p⁻-type base region 3, the n-type source region 4, the p⁻-type semiconductor region 5, and the p⁻-type semiconductor region 6. The source electrode 22 is electrically connected to the p⁻-type base region 3, the n-type source region 4, the p⁻-type semiconductor region 5, and the p⁻-type semiconductor region 6.

The first conductive portion 11 and the source electrode 22 are electrically isolated from each other by an insulating layer 11b. The second conductive portion 12 and the source electrode 22 are electrically isolated from each other by an insulating layer 12b. The first conductive portion 11 and the second conductive portion 12 are electrically connected to the gate pad 23.

As shown in FIGS. 2 and 3, on the first portion 2a, each of the p-type base region 3, the n-type source region 4, and the first conductive portion 11 is provided in a plurality in the X-direction. The p-type base region 3, the p⁻-type semiconductor region 5, the first conductive portion 11, and the second conductive portion 12 extend in the Y-direction. In the X-direction, the multiple p-type base regions 3 and the multiple first conductive portions 11 are alternately arranged.

FIG. 3 shows the structure of one end in the X-direction of the semiconductor device 100. The structure on the other end in the X-direction of the semiconductor device 100 is substantially symmetrical with the structure shown in FIG. 3. In other words, one second conductive portion 12 is provided on one end in the X-direction of the semiconductor device 100, and another second conductive portion 12 is provided on the other end in the X-direction of the semiconductor device 100. Multiple p⁻-type base regions 3, multiple n-type source regions 4, and multiple first conductive portions 11 are positioned between the pair of second conductive portions 12 that are separated from each other in the X-direction.

As shown in FIG. 2, the p⁻-type base region 3 may include a contact region 3a with a high p-type impurity concentration. As shown in FIG. 3, the p⁻-type semiconductor region 5 may include a contact region 5a with a high p-type impurity concentration. The p⁻-type semiconductor region 6 may include a contact region 6a with a high p-type impurity concentration. The contact region 3a, the contact region 5a, and the contact region 6a are in contact with the source electrode 22.

As shown in FIG. 2, on one p⁻-type base region 3, multiple contact regions 3a and multiple n-type source regions 4 are alternately arranged in the Y-direction. The length Ls in the Y-direction of the n-type source region 4 is longer than the length Lb in the Y-direction of the contact region 3a. The length Lb corresponds to the distance between adjacent n-type source regions 4 in the Y-direction.

The operation of the semiconductor device 100 will now be described. In a state where a positive voltage with respect to the source electrode 22 is applied to the drain electrode 21, a voltage exceeding a threshold is applied to the first conductive portion 11. As a result, a channel (an inversion layer) is formed in the p⁻-type base region 3. Electrons flow from the source electrode 22 to the n⁻-type drift region 2 through the channel; and the semiconductor device 100 is turned on. Thereafter, when the voltage applied to the first conductive portion 11 becomes lower than the threshold, the channel in the p⁻-type base region 3 disappears; and the semiconductor device 100 is turned off. The first conductive portion 11 functions as a gate electrode for controlling the flow of current in the semiconductor device 100.

On the p-type semiconductor region 5, there is no n-type semiconductor region electrically connected to the source electrode 22. Therefore, even when a voltage exceeding the threshold is applied to the second conductive portion 12, no current flows through the inversion layer in the p⁻-type semiconductor region 5.

When the semiconductor device 100 is turned off, collision ionization (avalanche breakdown) occurs in the vicinity of the lower end of the first conductive portion 11, the vicinity of the lower end of the second conductive portion 12, etc., due to the potential difference between the n-type drift region 2 and the first conductive portion 11, and the potential difference between the n⁻-type drift region 2 and the second conductive portion 12. Due to the collision ionization, a large number of carriers (electrons and holes) are generated. The electrons are discharged to the drain electrode 21 through the n⁻-type drift region 2. The holes are discharged to the source electrode 22 through the p-type base regions 3 and the p⁻-type semiconductor regions 5.

An example of the material of each component will now be described. The n⁺-type drain region 1, the n⁻-type drift region 2, the p″-type base region 3, the n-type source region 4, the p⁻-type semiconductor region 5 and the p-type semiconductor region 6 include silicon, silicon carbide, gallium nitride, or gallium arsenide as a semiconductor material. When silicon is used as the semiconductor material, arsenic, phosphorus, or antimony can be used as an n-type impurity. As a p-type impurity, boron can be used. The first conductive portion 11 and the second conductive portion 12 include a conductive material such as polysilicon. The first insulating layer 11a, the insulating layer 11b, the second insulating layer 12a, and the insulating layer 12b include an insulating material such as silicon oxide. The drain electrode 21, the source electrode 22, and the gate pad 23 include a metal such as titanium, gold, or aluminum.

Favorable ranges of the impurity concentrations in the semiconductor regions are as follows. The n-type impurity concentration in the n⁺-type drain region 1 is not less than 1.0×10¹⁹ atom/cm³ and not more than 1.0×10²¹ atom/cm³. The n-type impurity concentration in the n⁻-type drift region 2 is not less than 1.0×10¹⁶ atom/cm³ and not more than 1.0×10¹⁸ atom/cm³. The p-type impurity concentrations in the p⁻-type base region 3, the p⁻-type semiconductor region 5, and the p⁻-type semiconductor region 6 are not less than 1.0×10¹⁷ atom/cm³ and not more than 1.0×10¹⁹ atom/cm³. The n-type impurity concentration in the n-type source region 4 is not less than 5.0×10¹⁸ atom/cm³ and not more than 5.0×10²⁰ atom/cm³. The p-type impurity concentrations in the contact region 3a, the contact region 5a, and the contact region 6a are not less than 5.0×10¹⁸ atom/cm³ and not more than 5.0×10²⁰ atom/cm³.

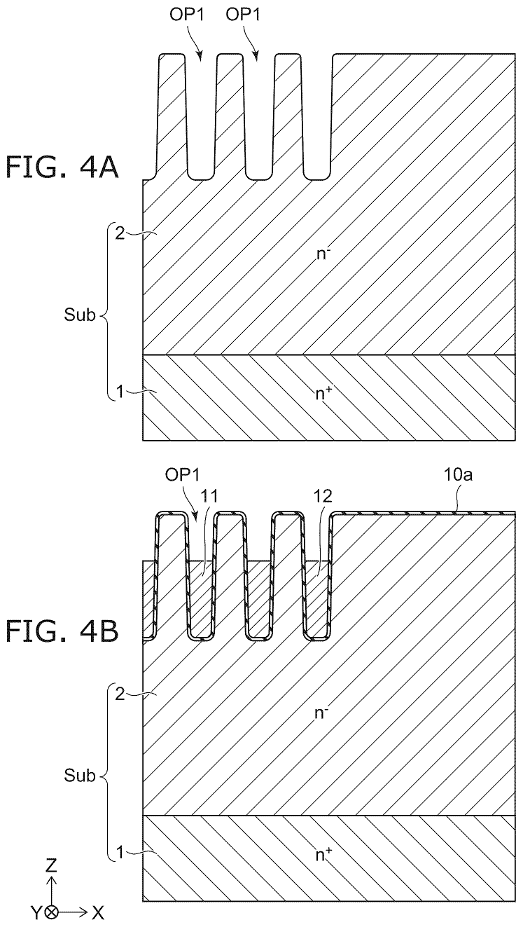

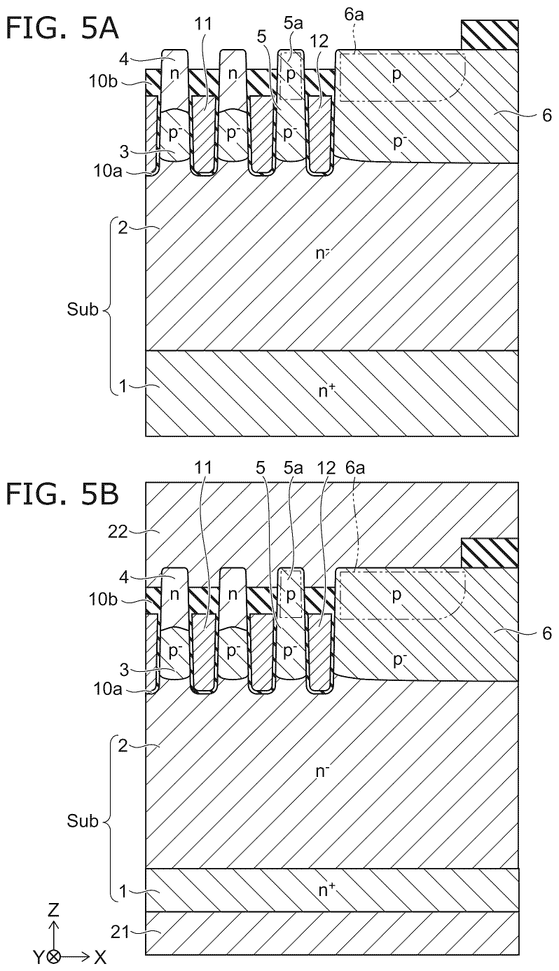

FIGS. 4A, 4B, 5A, and 5B are cross-sectional views illustrating a method for manufacturing the semiconductor device according to the embodiment.

An example of the manufacturing method for the semiconductor device 100 will now be described. First, a semiconductor substrate Sub including the n⁺-type drain region 1 and the n-type drift region 2 is prepared. As shown in FIG. 4A, multiple openings OP1 are formed on the upper surface of the n⁻-type drift region 2. The multiple openings OP1 are arranged in the X-direction, and each opening OP1 extends in the Y-direction.

The semiconductor substrate Sub is thermally oxidized. As a result, an insulating layer 10a is formed on the inner surfaces of the openings OP1 and on the upper surface of the n⁻-type drift region 2. A polysilicon layer filling the openings OP1 is formed by chemical vapor deposition (CVD). The upper surface of the polysilicon layer is caused to be retreated by etching. As shown in FIG. 4B, the second conductive portion 12 is formed inside the opening OP1 that is located at the end in the X-direction. The first conductive portions 11 are formed inside the other openings OP1, respectively.

P-type impurities and n-type impurities are sequentially ion-implanted, and the p⁻-type base region 3, the n-type source region 4, the p⁻-type semiconductor region 5, the p⁻-type semiconductor region 6 are formed in the upper part of the n⁻-type drift region 2. An insulating layer 10b covering the semiconductor regions is formed by CVD. As shown in FIG. 5A, the insulating layer 10b and the insulating layer 10a are etched to expose the upper surfaces of the n-type source region 4, the p⁻-type semiconductor region 5, and the p⁻-type semiconductor region 6.

A metal layer is formed by CVD or sputtering. The metal layer is patterned to form the source electrode 22 and the gate pad 23 (not shown). The lower surface of the n⁺-type drain region 1 is ground until the n⁺-type drain region 1 reaches a predetermined thickness. As shown in FIG. 5B, the drain electrode 21 is formed on the ground lower surface of the n⁺-type drain region 1 by sputtering. As described above, the semiconductor device 100 according to the embodiment is manufactured.

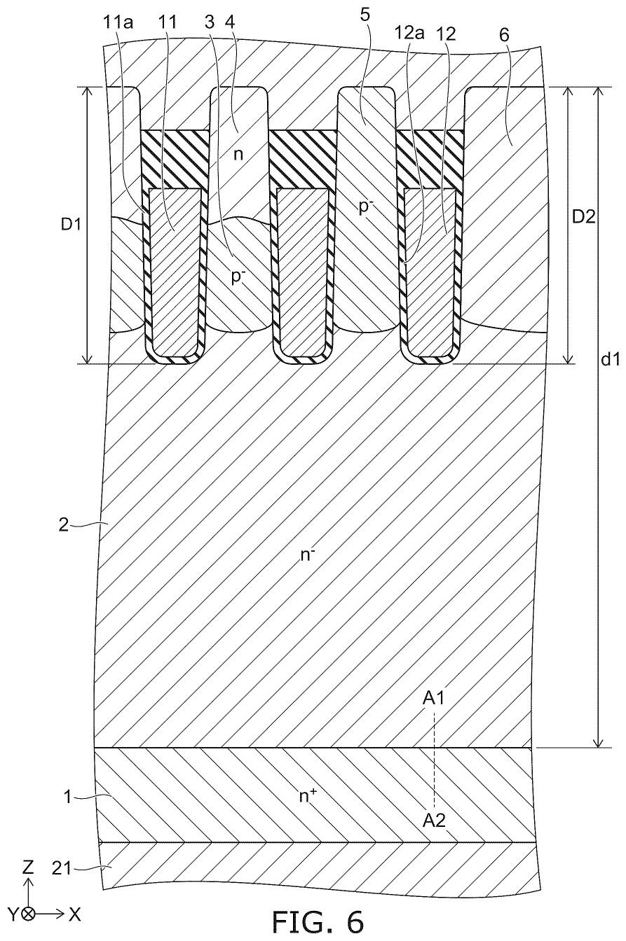

FIG. 6 is a partially enlarged cross-sectional view of FIG. 3.

In the semiconductor device 100, the ratio of a distance d1 to a depth D1 is not less than 2.3 and less than 3. The ratio of the distance d1 to a depth D2 is not less than 2.3 and less than 3. As shown in FIG. 6, the depth D1 (a first depth) is the depth in the Z-direction from the upper surface of the n-type source region 4 to the lower end of the first insulating layer 11a. The depth D2 (a second depth) is the depth in the Z-direction from the upper surface of the n-type source region 4 to the lower end of the second insulating layer 12a. The distance d1 is the distance in the Z-direction from the upper surface of the n-type source region 4 to the boundary between the n⁺-type drain region 1 and the n⁻-type drift region 2.

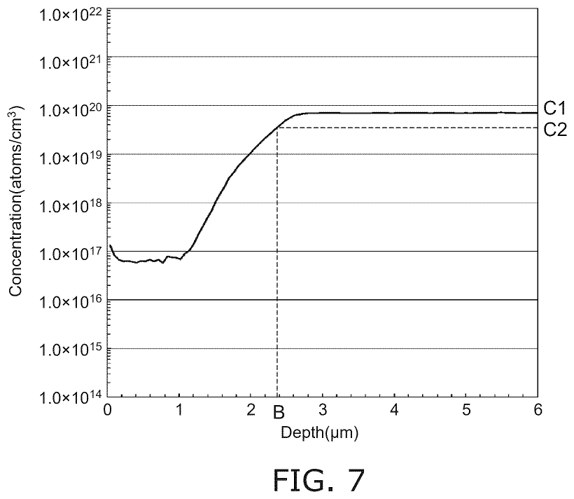

FIG. 7 is a graph illustrating a profile of the n-type impurity concentration in the semiconductor device according to the embodiment.

FIG. 7 shows the profile of the n-type impurity concentration in the A1-A2 line of FIG. 6. In FIG. 7, the horizontal axis represents the depth (a position in the Z-direction). The vertical axis represents the n-type impurity concentration [atm/cm³] at each point in the Z-direction. As for the horizontal axis, an arbitrary position in the n⁻-type drift region 2 is set to be 0 μm. The horizontal axis shows the depth up to the n⁺-type drain region 1.

The boundary between the n⁺-type drain region 1 and the n⁻-type drift region 2 is determined based on the n-type impurity concentration in the n⁺-type drain region 1. Specifically, first, the concentration C1 of the n-type impurity in the n⁺-type drain region 1 is measured at a position sufficiently away from the drain electrode 21 and the n-type drift region 2. The concentration C2 which is 0.5 times the concentration C1 is calculated. As shown in FIG. 7, the n-type impurity concentration decreases from the n⁺-type drain region 1 to the n⁻-type drift region 2. The point where the n-type impurity concentration reaches C2 is defined as the boundary B between the n⁺-type drain region 1 and the n-type drift region 2.

Advantages of the embodiment will now be described.

The semiconductor device 100 includes a parasitic transistor consisting of the n-type drift region 2, the p⁻-type base region 3, and the n-type source region 4. As described above, when the semiconductor device 100 is turned off, carriers are generated by collision ionization. At this time, the potential of the p⁻-type base region 3 is raised due to the holes, and the parasitic transistor may operate. If a large current flows through the semiconductor device 100 due to the operation of the parasitic transistor, there is a possibility that the semiconductor device 100 may undergo breakdown. Therefore, it is desirable that the parasitic transistor is less likely to operate.

The semiconductor device 100 includes the p⁻-type semiconductor region 5 and the p⁻-type semiconductor region 6. When collision ionization occurs in the vicinity of the lower end of the second conductive portion 12, the holes flow mainly to the p⁻-type semiconductor region 5 and the p⁻-type semiconductor region 6. An n-type semiconductor region such as the n-type source region 4 is not provided on the p⁻-type semiconductor region 5 and the p⁻-type semiconductor region 6. At the height (position in the Z-direction) where the n-type source region 4 is provided, there are a part of the p⁻-type semiconductor region 5 and a part of the p⁻-type semiconductor region 6. In other words, there are no parasitic transistors in the regions where the p⁻-type semiconductor region 5 and the p⁻-type semiconductor region 6 are provided. When collision ionization is more likely to occur in the vicinity of the lower end of the second conductive portion 12 than in the vicinity of the lower end of the first conductive portion 11, more holes flow to the p⁻-type semiconductor region 5 and the type semiconductor region 6 compared to the p⁻-type base region 3. Therefore, in order to suppress the operation of the parasitic transistor, it is preferable that collision ionization is more likely to occur in the vicinity of the lower end of the second conductive portion 12 than in the vicinity of the lower end of the first conductive portion 11.

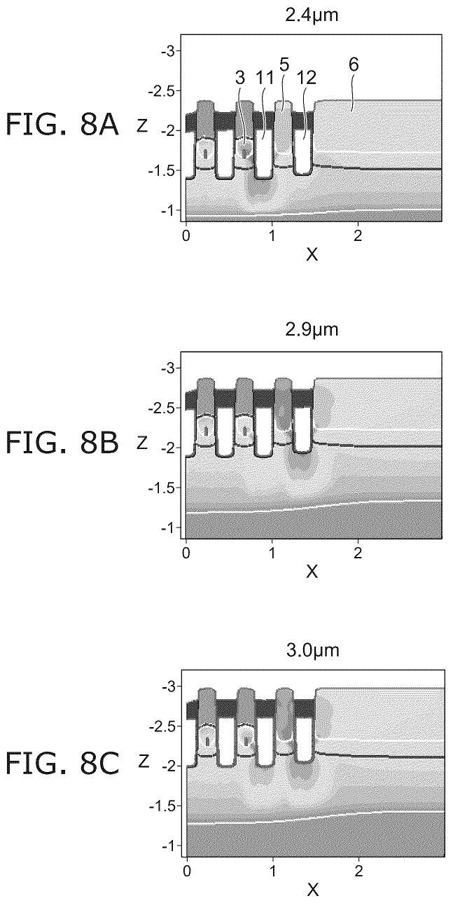

FIGS. 8A to 8C are simulation results showing characteristics of the semiconductor device according to the embodiment.

FIGS. 8A to 8C show the current density of holes at the time of turn-off. The darker the color, the greater the current density. FIGS. 8A to 8C show simulation results when the depths D1 and D2 shown in FIG. 6 are constant and the distance d1 is changed.

Specifically, in the simulation, the depths D1 and D2 are set to 1.02 μm. The thickness in the Z-direction of the p-type base region 3 is set to 0.38 μm. The thickness in the Z-direction of the n-type source region 4 is set to 0.45 μm. The thickness in the Z-direction of each of the p⁻-type semiconductor region 5 and the p⁻-type semiconductor region 6 is set to 0.8 μm. The positions in the Z-direction of the upper surfaces of the n-type source region 4, the p⁻-type semiconductor region 5, and the p⁻-type semiconductor region 6 are the same as each other. Under these conditions, the change in the current density of holes was examined as the distance d1 was changed from 2.4 μm to 3.0 μm.

FIG. 8A shows the simulation result when the distance d1 is 2.4 μm. In the simulation result shown in FIG. 8A, the current density in the vicinity of the lower end of the first conductive portion 11 is greater than the current density in the vicinity of the lower end of the second conductive portion 12. The current density in the p⁻-type base region 3 is greater than the current density in the p⁻-type semiconductor region 5 and the current density in the p⁻-type semiconductor region 6. Thus, the electric potential of the p⁻-type base region 3 rises more easily than the electric potential of the p⁻-type semiconductor region 5 and the electric potential of the p⁻-type semiconductor region 6.

FIG. 8B shows the simulation result when the distance d1 is 2.9 μm. In the simulation results shown in FIG. 8B, the current density in the vicinity of the lower end of the second conductive portion 12 is greater than the current density in the vicinity of the lower end of the first conductive portion 11. The current density in the p⁻-type semiconductor region 5 is greater than the current density in the p⁻-type base region 3. Thus, the increase in the electric potential of the p⁻-type base region 3 is suppressed compared to the increase in the electric potential of the p-type semiconductor region 5.

FIG. 8C shows the simulation result when the distance d1 is 3.0 μm. In the simulation result shown in FIG. 8C, the current density in the vicinity of the lower end of the second conductive portion 12 is greater than the current density in the vicinity of the lower end of the first conductive portion 11, as in the simulation result shown in FIG. 8B. Thus, the increase in the electric potential of the p⁻-type base region 3 is suppressed.

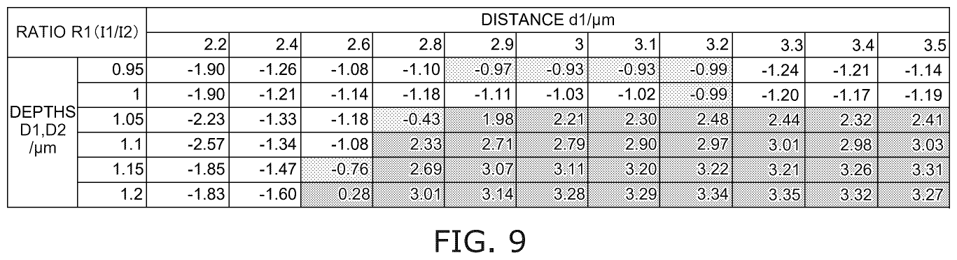

FIGS. 9 to 11 are other simulation results showing the characteristics of the semiconductor device according to the embodiment.

FIG. 9 shows the simulation results of the ratio of the hole current I1 to the hole current I2 when the depth D1, depth D2, and distance d1 are changed. In the simulation, the distance d1 was changed from 2.2 μm to 3.2 μm, and the depth D1 and depth D2 were changed from 0.95 μm to 1.2 μm. The other simulation conditions are the same as those of the simulations in which the results shown in FIGS. 8A to 8C were obtained. In the simulations described hereinbelow, the depth D1 and the depth D2 are set to the same value. Therefore, the simulation results for the depth D1 can be read as the simulation results for the depth D2.

In FIG. 9, the vertical axis represents the ratio R1(I1/I2) of the hole current I1 to the hole current I2. The hole current I1 is the density of hole current flowing through the p⁻-type semiconductor region 5. The hole current I2 is the density of hole current flowing through the p⁻-type base region 3 adjacent to the p⁻-type semiconductor region 5. The numerical values on the vertical axis are expressed in logarithms (Log scale). Therefore, when the hole current I1 is greater than the hole current I2, the numerical value on the vertical axis is positive. When the hole current I2 is greater than the hole current I1, the numerical value on the vertical axis is negative.

From the simulation results shown in FIG. 9, when the depth D1 is not less than 1.05 μm and the distance d1 is not less than 2.8 μm, the ratio R1 is −0.5 or more. For example, when the depth D1 is 1.05 μm and the distance d1 is 2.9 μm, the ratio R1 is −0.43. This indicates that although the hole current I2 is greater than the hole current I1, the hole current I2 is almost equal to the hole current I1. Therefore, the increase in the electric potential of the p⁻-type base region 3 is suppressed.

In particular, when the depth D1 is greater than 1.05 μm and the distance d1 is greater than 2.8 μm, the ratio R1 is a positive value. In other words, the hole current I1 is greater than the hole current I2, and the increase in the electric potential of the p⁻-type base region 3 is effectively suppressed.

The details of why the hole current I1 can be increased as the depth D1, depth D2, and distance d1 are greater are unknown, but it is presumed as follows. When the depths D1 and D2 are small and the distance d1 is small, the potential gradients between the drain electrode 21 and the lower end of the first conductive portion 11 and between the drain electrode 21 and the lower end of the second conductive portion 12 are large. In such a case, as shown in the simulation results described above, it was confirmed that more holes flowed through the p-type base region 3. On the other hand, when the depths D1 and D2 are large and the distance d1 is large, the potential gradients between the drain electrode 21 and the lower end of the first conductive portion 11 and between the drain electrode 21 and the lower end of the second conductive portion 12 are reduced. When holes are generated in the vicinity of the lower end of the first insulating layer 11a and in the vicinity of the lower end of the second insulating layer 12a, the acceleration of the holes in the Z-direction is reduced. As a result, the lateral movement distance of the holes may increase. In addition, while the n-type source region 4 is provided on the p-type base region 3, no n-type semiconductor region is provided on the p⁻-type semiconductor region 5. In this case, the electric field formed by the p-n junction between the n⁻-type drift region 2 and the p⁻-type semiconductor region 5 is stronger than the electric field formed by the p-n junction between the n⁻-type drift region 2 and the p⁻-type base region 3. It is presumed that the holes move more easily toward the p⁻-type semiconductor region 5, resulting in the hole current I1 becoming greater than the hole current I2.

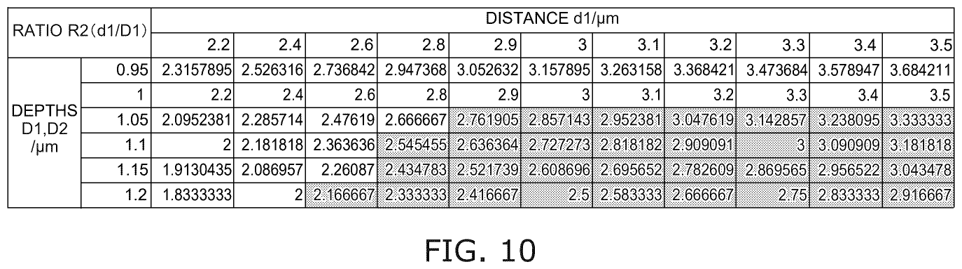

For each simulation result shown in FIG. 9, the ratio R2 (d1/D1) of the distance d1 to the depth D1 was calculated. FIG. 10 shows the results. From the comparison between the simulation results shown in FIG. 9 and the ratios shown in FIG. 10, it can be seen that the hole current I1 can be sufficiently large when the ratio R2 is not less than 2.15. From the simulation results shown in FIGS. 9 and 10, when the depth D1 is not less than 1.05 μm, the distance d1 is not less than 2.8 μm, and the ratio R2 is not less than 2.15, the hole current I1 is sufficiently large, and the increase in electric potential of the p⁻-type base region 3 is suppressed.

In addition, from the simulation results of FIGS. 9 and 10, when the depth D1 is not less than 1.05 μm and the distance d1 is not less than 2.8 μm, the greater the ratio R2 of the distance d1 to the depth D1, the larger the ratio R1 of the hole current I1 to the hole current I2. In other words, the greater the ratio R2 is, the more the increase in the electric potential of the p-type base region 3 is suppressed.

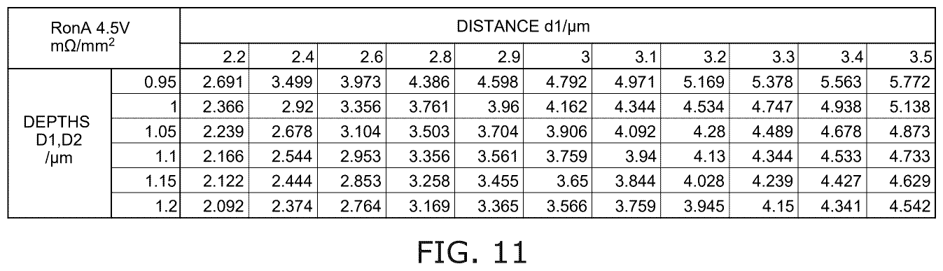

On the other hand, the greater the distance d1, the greater the on-resistance of the semiconductor device 100. Therefore, from the viewpoint of the on-resistance, it is desirable for the distance d1 to be small. The simulation results of FIG. 11 show the relationship between depth D1, distance d1, and on-resistance RonA. The on-resistance RonA indicates the electrical resistance per unit area when a voltage of 4.5 V is applied to the semiconductor device 100. From the simulation results shown in FIG. 11, it can be seen that the on-resistance RonA increases as the distance d1 increases.

The following can be seen from the simulation results shown in FIG. 11. In a case where the depth D1 is 1.05 μm, when the distance d1 is not more than 3.2 μm, the increase in the on-resistance RonA can be suppressed to less than 25% of the on-resistance RonA when the distance d1 is 2.8 μm. Similarly, in cases where the depth D1 is 1.1 μm, 1.15 μm, or 1.2 μm, when the distance d1 is not more than 3.2 μm, the increase in the on-resistance RonA can be suppressed to less than 25% of the on-resistance RonA when the distance d1 is 2.8 μm.

From the table shown in FIG. 10, when the distance d1 is not more than 3.2 μm, the ratio R2 is not more than 3.05. In other words, when the ratio R2 is not less than 2.15 and not more than 3.05, the hole current I1 can be increased while suppressing the increase in the on-resistance RonA. Preferably, the ratio R2 is not more than 2.95. More preferably, the ratio R 2 is not more than 2.85.

According to the embodiment, the depth D1 is not less than 1.05 μm, the distance d1 is not less than 2.8 μm, and the ratio of the distance d1 to the depth D1 and the ratio of the distance d1 to the depth D2 are not less than 2.15 and not more than 3.05. Therefore, the flow of holes to the p-type base region 3 can be suppressed. As a result, the operation of the parasitic transistor can be suppressed, and the breakdown capability of the semiconductor device 100 can be improved.

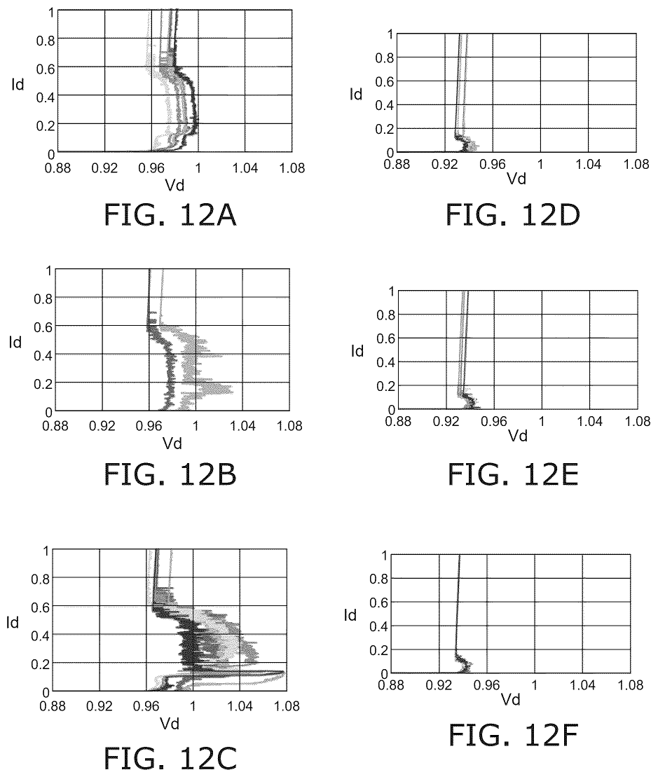

FIGS. 12A to 12F are other simulation results showing the characteristics of the semiconductor device according to the embodiment.

In order to reduce the on-resistance of the semiconductor device 100, the length Ls shown in FIG. 2 is preferably longer than the length Lb. The greater the ratio of the length Ls to the length Lb, the lower the on-resistance. On the other hand, when the proportion of length Lb decreases, the holes flowing in the p-type base region 3 becomes difficult to be discharged to the source electrode 22. As a result, the parasitic transistor operates more easily.

FIGS. 12A to 12F show the current-voltage characteristics when the ratio of the length Ls to the length Lb is changed. The horizontal axis represents the voltage Vd of the drain electrode 21 with respect to the source electrode 22. The vertical axis represents the current Id flowing from the drain electrode 21 to the source electrode 22. In the simulation in which the results of FIGS. 12A to 12C were obtained, the distance d1 was set to 2.7 μm. The other simulation conditions are the same as those of the simulations from which the results of FIGS. 8A to 8C and FIG. 9 were obtained. FIGS. 12A to 12C respectively show simulation results when the ratio of the length Ls to the length Lb is 3, 5, and 7.

From the simulation results shown in FIGS. 12a to 12C, in a case where the ratio of length Ls to the length Lb is not less than 5, it can be seen that the current Id changes significantly when the relative ratio of Vd is about 0.98. This indicates that the parasitic transistor is operating.

In the simulations in which the results of FIGS. 12D to 12F were obtained, the distance d1 was set to 3.1 μm. FIGS. 12D to 12F respectively show simulation results when the ratio of the length Ls to the length Lb is 3, 5, and 7. From the simulation results shown in FIGS. 12D to 12F, it can be seen that the change in the current Id is very small even when the ratio of the length Ls to the length Lb is not less than 5. This indicates that the operation of the parasitic transistor is well suppressed.

In order to sufficiently reduce the on-resistance of the semiconductor device 100, the ratio of the length Ls to the length Lb is preferably not less than 5. According to the embodiment, even when the ratio of the length Ls to the length Lb is not less than 5, the ratio of the distance d1 to the depth D1 (or the depth D2) is not less than 2.25 and not more than 3. While suppressing the operation of the parasitic transistor, the on-resistance of the semiconductor device 100 can be reduced.

On the other hand, when the ratio of the length Ls to the length Lb is excessively large, even if the ratio of the distance d1 to the depth D1 (or the depth D2) is not less than 2.25 and not more than 3, the operation of the parasitic transistor may not be sufficiently suppressed. Therefore, it is preferable that the ratio of the length Ls to the length Lb is not less than 5 and not more than 9. More preferably, the ratio of the length Ls to the length Lb is not less than 5 and not more than 7.

### Modification

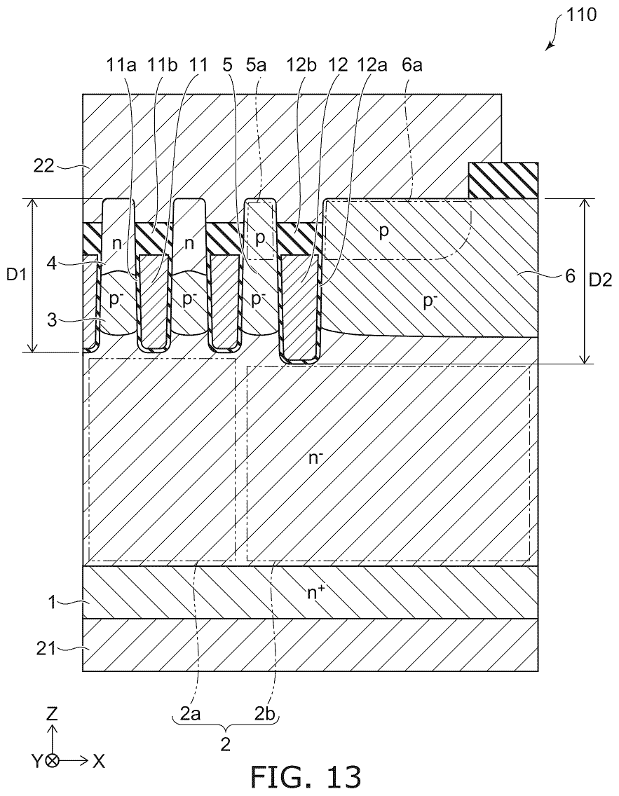

FIG. 13 is a cross-sectional view illustrating a part of a semiconductor device according to a modification of the embodiment.

In the simulations described above, the depth D1 and the depth D2 are the same. In the semiconductor device 110 shown in FIG. 13, the depth D2 is different from the depth D1. When the depth D1 and the depth D2 are greater than 2.9 μm and less than 3.2 μm, the depth D1 and the depth D2 may be different from each other. For example, since the depth D2 is greater than the depth D1, collision ionization occurs more easily in the vicinity of the lower end of the second conductive portion 12. As a result, the operation of the parasitic transistor can be more suppressed in the semiconductor device 110.

Embodiments of the present invention include the following features.

### Feature 1

A semiconductor device, including:
a first electrode;
a first semiconductor region of a first conductivity type provided on the first electrode;
a second semiconductor region of the first conductivity type provided on the first semiconductor region, an impurity concentration of the first conductivity type in the second semiconductor region being less than an impurity concentration of the first conductivity type in the first semiconductor region, the second semiconductor region including a first portion and a second portion located around the first portion along a first plane that is perpendicular to a first direction from the first electrode to the first semiconductor region;
a third semiconductor region of a second conductivity type provided on the first portion;
a fourth semiconductor region of the first conductivity type provided on the third semiconductor region;
a first conductive portion facing the third semiconductor region via a first insulating layer in a second direction that is perpendicular to the first direction, a first depth in the first direction from an upper surface of the fourth semiconductor region to a lower end of the first insulating layer being not less than 1.05 μm, a distance in the first direction from the upper surface of the fourth semiconductor region to a boundary between the first semiconductor region and the second semiconductor region is not less than 2.8 μm, a ratio of the distance to the first depth being not less than 2.15 and not more than 3.05;
a fifth semiconductor region of the second conductivity type provided on the second portion;
a second conductive portion facing the fifth semiconductor region via a second insulating layer in the second direction, a second depth in the first direction from the upper surface of the fourth semiconductor region to a lower end of the second insulating layer being not less than 1.05 μm, a ratio of the distance to the second depth being not less than 2.15 and not more than 3.05; and
a second electrode provided on the third semiconductor region, the fourth semiconductor region, and the fifth semiconductor region.

### Feature 2

The semiconductor device according to feature 1, in which
the third semiconductor region includes
   a channel portion facing the first conductive portion in the second direction, and
   a contact portion in contact with the second electrode,
an impurity concentration of the second conductivity type in the contact portion is greater than an impurity concentration of the second conductivity type in the channel portion, and
the contact portion is arranged with the fourth semiconductor region in a third direction that is perpendicular to the first direction and the second direction.

### Feature 3

The semiconductor device according to feature 2, in which
a ratio of a length in the third direction of the fourth semiconductor region to a length in the third direction of the contact portion is not less than 5 and not more than 9.

### Feature 4

The semiconductor device according to feature 3, in which
a plurality of the contact portions and a plurality of the fourth semiconductor regions are alternately arranged in the third direction.

### Feature 5

The semiconductor device according to any one of features 1 to 4, in which
the distance is not less than 2.8 μm and not more than 3.2 μm.

### Feature 6

The semiconductor device according to any one of features 1 to 5, in which
the ratio of the distance to the first depth is not less than 2.15 and not more than 2.95, and
the ratio of the distance to the second depth is not less than 2.15 and not more than 2.95.

### Feature 7

The semiconductor device according to any one of features 1 to 6, in which
a lower end of the second conductive portion is positioned lower than a lower end of the first conductive portion.

In the embodiments above, the relative levels of the impurity concentrations between the semiconductor regions can be confirmed using, for example, a scanning capacitance microscope (SCM). The carrier concentration in each semiconductor region can be considered to be equal to the activated impurity concentration in each semiconductor region. Accordingly, the relative levels of the carrier concentrations between the semiconductor regions also can be confirmed using SCM. The impurity concentration in each semiconductor region can be measured, for example, using secondary ion mass spectrometry (SIMS).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device, comprising:
a first electrode;
a first semiconductor region of a first conductivity type provided on the first electrode;
a second semiconductor region of the first conductivity type provided on the first semiconductor region, an impurity concentration of the first conductivity type in the second semiconductor region being less than an impurity concentration of the first conductivity type in the first semiconductor region, the second semiconductor region including a first portion and a second portion located around the first portion along a first plane that is perpendicular to a first direction from the first electrode to the first semiconductor region;
a third semiconductor region of a second conductivity type provided on the first portion;
a fourth semiconductor region of the first conductivity type provided on the third semiconductor region;
a first conductive portion facing the third semiconductor region via a first insulating layer in a second direction that is perpendicular to the first direction, a first depth in the first direction from an upper surface of the fourth semiconductor region to a lower end of the first insulating layer being not less than 1.05 μm, a distance in the first direction from the upper surface of the fourth semiconductor region to a boundary between the first semiconductor region and the second semiconductor region is not less than 2.8 μm, a ratio of the distance to the first depth being not less than 2.15 and not more than 3.05;
a fifth semiconductor region of the second conductivity type provided on the second portion;
a second conductive portion facing the fifth semiconductor region via a second insulating layer in the second direction, a second depth in the first direction from the upper surface of the fourth semiconductor region to a lower end of the second insulating layer being not less than 1.05 μm, a ratio of the distance to the second depth being not less than 2.15 and not more than 3.05; and
a second electrode provided on the third semiconductor region, the fourth semiconductor region, and the fifth semiconductor region.

2. The semiconductor device according to claim 1, wherein
the third semiconductor region includes
a channel portion facing the first conductive portion in the second direction, and
a contact portion in contact with the second electrode,
an impurity concentration of the second conductivity type in the contact portion is greater than an impurity concentration of the second conductivity type in the channel portion, and
the contact portion is arranged with the fourth semiconductor region in a third direction that is perpendicular to the first direction and the second direction.

3. The semiconductor device according to claim 2, wherein
a ratio of a length in the third direction of the fourth semiconductor region to a length in the third direction of the contact portion is not less than 5 and not more than 9.

4. The semiconductor device according to claim 3, wherein
a plurality of the contact portions and a plurality of the fourth semiconductor regions are alternately arranged in the third direction.

5. The semiconductor device according to claim 1, wherein
the distance is not less than 2.8 μm and not more than 3.2 μm.

6. The semiconductor device according to claim 1, wherein
the ratio of the distance to the first depth is not less than 2.15 and not more than 2.95, and
the ratio of the distance to the second depth is not less than 2.15 and not more than 2.95.

7. The semiconductor device according to claim 1, wherein
a lower end of the second conductive portion is positioned lower than a lower end of the first conductive portion.
